(19) United States
(12) Patent Application Publication
(10) Pub. No.: US 2024/0258126 A1
(43) Pub. Date: Aug. 1, 2024

(54) SEMICONDUCTOR WAFER CLEANING DEVICE, SEMICONDUCTOR WAFER CLEANING METHOD, AND METHOD FOR MANUFACTURING SILICON WAFER

(71) Applicant: SUMCO Corporation, Tokyo (JP)

(72) Inventors: Kaito NODA, Tokyo (JP); Kazuhiro OHKUBO, Tokyo (JP); Michihiko TOMITA, Tokyo (JP); Daichi YAMAURA, Tokyo (JP); Makoto TAKEMURA, Tokyo (JP); Koichi OKUDA, Tokyo (JP)

(73) Assignee: SUMCO Corporation, Tokyo (JP)

(21) Appl. No.: 18/561,531

(22) PCT Filed: Mar. 7, 2022
(86) PCT No.: PCT/JP2022/009779

§ 371 Date: Nov. 16, 2023

(30) Foreign Application Priority Data
May 21, 2021 (JP) 2021-086502

(51) Int. Cl. H01L 21/67; H01L 21/02; H01L 21/687

(52) U.S. Cl. CPC H01L 21/67051; H01L 21/02052; H01L 21/0209; H01L 21/68785

(57) ABSTRACT

A semiconductor wafer cleaning apparatus that can suppress the generation of particles on the back surface of the semiconductor wafer. A semiconductor wafer cleaning apparatus comprises a rotary table having an opening in the center; a wafer holder provided on the top surface of the rotary table; a return portion provided on the bottom surface of the rotary table; a nozzle head having a centrally located recess and a horizontal portion disposed on the radially outer side of the recess; a lower chemical supply nozzle; and a wafer back surface rinse nozzle, the return portion is disposed near the opening, and a return portion rinse nozzle is provided in the recess of the nozzle head to supply pure water toward the return portion to rinse the return portion.

### TECHNICAL FIELD

This disclosure relates to a semiconductor wafer cleaning apparatus, a method for cleaning a semiconductor wafer, and a method for producing a silicon wafer.

### BACKGROUND

Conventionally, silicon wafers have been used as substrates for semiconductor devices. The silicon wafers are obtained by subjecting an ingot of single-crystal silicon grown by the Czochralski (CZ) method or other methods to wafer processing process. Since particles such as polishing dust adhere to the surface of silicon wafers during the above processing process, the silicon wafers are cleaned to remove the particles after processing.

The apparatus for cleaning semiconductor wafers, such as silicon wafers, includes batch-type cleaning apparatus that cleans multiple semiconductor wafers simultaneously and single-wafer cleaning apparatus that cleans semiconductor wafers one at a time. Among other reasons, the single-wafer cleaning apparatus has been used in recent years because it requires relatively little cleaning solution, cross-contamination between semiconductor wafers can be avoided, and it is becoming increasingly difficult to process multiple semiconductor wafers simultaneously due to their larger diameters.

FIG. 1 illustrates an example of a conventional semiconductor wafer cleaning apparatus. The semiconductor wafer cleaning apparatus 100 illustrated in FIG. 1 comprises a disc-shaped rotary table 11 (also referred to as a “decorated cup”) having a circular opening 11a in the center and positioned horizontally, and a wafer holder 12 provided on the top surface 11b of the rotary table 11 to hold a semiconductor wafer W to be cleaned.

The cleaning apparatus 100 comprises, below the rotary table 11, a nozzle head 14 having a centrally located inverted conical recess 14a which shrinks in diameter as it moves vertically downward, and a horizontal portion 14b disposed horizontally on radially outer side of the recess 14a, opposite to the bottom surface of the rotary table 11. A liquid drainage port 14c is provided at the bottom of the recess 14a and is connected to a liquid drainage nozzle (not shown).

The recess 14a of the nozzle head 14 is provided with a lower chemical supply nozzle 15 that supplies chemical solution toward the back surface of the semiconductor wafer W through the opening 11a, and a wafer back surface rinse nozzle 16 that supplies pure water toward the back surface of the semiconductor wafer W through the opening 11a.

On the other hand, above the semiconductor wafer W, an upper chemical supply nozzle 17 that supplies chemical solution toward the front surface of the semiconductor wafer W and a wafer front surface rinse nozzle 18 that supplies pure water toward the front surface of the semiconductor wafer W are provided.

The bottom surface 11c of the above rotary table 11 is provided with a cylindrical return portion 13 that restrains the entry of chemical solution between the bottom surface 11c of the rotary table 11 and the nozzle head 14. The return portion 13 is provided along the inner wall lid of the rotary table 11 defining the opening 11a of the rotary table 11 (i.e., the inner wall 13a of the return portion 13 and the inner wall lid of the rotary table 11 are flush). Also, a spin cup 19 is provided on the radially outer side of the rotary table 11 to catch and collect the chemical solution or pure water that splashed outside the rotary table 11 during the cleaning and rinsing processes of the semiconductor wafer W.

The cleaning of semiconductor wafer W using the above cleaning apparatus 100 is performed, for example, as follows. First, a drive unit (not shown) rotates the rotary table 11 at a predetermined rotational speed to rotate the semiconductor wafer W. At the same time, chemical solution such as hydrofluoric acid (HF) is supplied from the lower chemical supply nozzle 15 and the upper chemical supply nozzle 17 to remove polishing powder, etc. from the front and back surfaces of the semiconductor wafer W, such as silicon wafer (Cleaning process).

Next, with the semiconductor wafer W rotated, the supply of chemical solution from the lower chemical supply nozzle 15 and the upper chemical supply nozzle 17 is stopped, and pure water is supplied from the wafer back surface rinse nozzle 16 and the wafer front surface rinse nozzle 18 to rinse the front and back surfaces of the semiconductor wafer W (Rinsing process).

Then, the supply of pure water from the wafer back surface rinse nozzle 16 and the wafer front surface rinse nozzle 18 is stopped, the rotational speed of the semiconductor wafer W is increased, and a gas such as nitrogen (N₂) is supplied from a gas supply nozzle (not shown) to dry the front and back surfaces of the semiconductor wafer W (Drying process). In this way, the semiconductor wafer W can be cleaned.

As described above, during the cleaning process in which the chemical solution such as HF is supplied to the back surface of the semiconductor wafer W, the chemical solution splashes onto the rotary table 11 and the nozzle head 14. Thus, during the subsequent drying process, the scattered chemicals may adhere to the back surface of the semiconductor wafer W by the airflow generated by the high-speed rotation of the rotary table 11. In such cases, etching marks and particles will be formed on the back surface of the wafer.

In order to suppress the generation of etching marks and particles on the back surface of the wafer, PTL 1 describes a technology for cleaning the rotary table and nozzle head by varying the spray speed of the rinse solution, when supplying the rinse solution such as pure water from the nozzle toward the back surface of the semiconductor wafer, by means of speed control.

### CITATION LIST

### Patent Literature

PTL 1: JP2005-217138A

### SUMMARY

### Technical Problem

However, the inventors have found that particles are still generated on the back surface of the semiconductor wafer even with the technology described in PTL 1, and a technology that can suppress the particle generation is desired.

The present disclosure was made in view of the above-mentioned problems, and its object is to propose a semiconductor wafer cleaning apparatus, a method for cleaning a semiconductor wafer, and a method for producing a silicon wafer, that can suppress the generation of particles on the back surface of the semiconductor wafer.

### Solution to Problem

The present disclosure, which solves the above problem, is as follows:

[1] A semiconductor wafer cleaning apparatus comprising:
a disk-shaped rotary table having a circular opening in the center and positioned horizontally;
a wafer holder provided on the top surface of the rotary table to hold a semiconductor wafer to be cleaned;
a cylindrical return portion provided on the bottom surface of the rotary table;
a nozzle head having a centrally located inverted conical recess, and a horizontal portion disposed horizontally on the radially outer side of the recess, opposite to the bottom surface of the rotary table;
a lower chemical supply nozzle provided in the recess of the nozzle head to supply chemical solution toward the back surface of the semiconductor wafer through the opening; and
a wafer back surface rinse nozzle provided in the recess of the nozzle head to supply pure water toward the back surface of the semiconductor wafer through the opening; wherein,
the return portion is disposed near the opening, and
a return portion rinse nozzle is provided in the recess of the nozzle head to supply pure water toward the return portion to rinse the return portion.

[2] The semiconductor wafer cleaning apparatus according to above [1], wherein the return portion is disposed at a position radially outward from an inner wall of the rotary table defining the opening.

[3] The semiconductor wafer cleaning apparatus according to above [2], wherein the return portion is disposed at a position of 1 mm or more to 20 mm or less radially outward from the inner wall of the rotary table defining the opening.

[4] The semiconductor wafer cleaning apparatus according to any one of above [1] to [3], wherein a plurality of the return portion rinse nozzles is provided.

[5] The semiconductor wafer cleaning apparatus according to above [4], wherein the plurality of return portion rinse nozzles is disposed at least 90 degrees apart from each other in the circumferential direction of the recess.

[6] The semiconductor wafer cleaning apparatus according to above [4] or [5], wherein the plurality of return portion rinse nozzles includes a first return portion rinse nozzle, and a second return portion rinse nozzle disposed radially inward from the first return portion rinse nozzle.

[7] The semiconductor wafer cleaning apparatus according to above [6], wherein a spray port for spraying pure water in the second return portion rinse nozzle protrudes from the surface of the recess.

[8] The semiconductor wafer cleaning apparatus according to any one of above [1] to [7], further comprising a gas supply nozzle provided in the recess of the nozzle head to supply gas toward the back surface of the semiconductor wafer thorough the opening, the gas supply nozzle is disposed at least 90 degrees away from the return portion rinse nozzle in the direction of rotation of the rotary table.

[9] The semiconductor wafer cleaning apparatus according to any one of above [1] to [8], wherein the return portion rinse nozzle is disposed to spray pure water toward the return portion at an angle of 0 or more to 30 or less degrees to the vertical direction.

[10] A method for cleaning a semiconductor wafer to be cleaned using the semiconductor wafer cleaning apparatus according to any one of above [1] to [9], wherein the method includes:
supplying pure water from the wafer back surface rinse nozzle toward the back surface of the semiconductor wafer to rinse the back surface of the semiconductor wafer, and simultaneously supplying pure water from the return portion rinse nozzle toward the return portion to rinse the return portion.

[11] The method for cleaning a semiconductor wafer according to above [10], wherein the method includes supplying chemical solution from the lower chemical supply nozzle toward the back surface of the semiconductor wafer, and simultaneously supplying pure water from the return portion rinse nozzle toward the return portion to rinse the return portion.

[12] The method for cleaning a semiconductor wafer according to above [10] or [11], wherein the method includes using the semiconductor wafer cleaning apparatus according to any one of above [4] to [7] to simultaneously supply pure water from the plurality of return portion rinse nozzles toward the return portion.

[13] The method for cleaning a semiconductor wafer according to above [12], wherein the method includes using the semiconductor wafer cleaning apparatus according to above [6] or [7] to make the flow rate of pure water from the first return portion rinse nozzle greater than the flow rate of pure water from the second return portion rinse nozzle.

[14] The method for cleaning a semiconductor wafer according to any one of above [10] to [13], wherein the method includes using the semiconductor wafer cleaning apparatus according to above [8] to supply gas from the gas supply nozzle toward the back surface of the semiconductor wafer during at least rinsing the back surface of the semiconductor wafer with pure water.

[15] The method for cleaning a semiconductor wafer according to any one of above [10] to [14], wherein the semiconductor wafer is a silicon wafer.

[16] A method for producing a silicon wafer, wherein the method includes using the method for cleaning a semiconductor wafer according to above [15] to clean a silicon wafer obtained by subjecting a single-crystal silicon ingot grown by a prescribed method to a wafer processing process.

### Advantageous Effect

According to the present disclosure, the particle generation on the back surface of the semiconductor wafer can be suppressed.

### BRIEF DESCRIPTION OF THE DRAWINGS

In the accompanying drawings:

FIG. 1 illustrates an example of a conventional semiconductor wafer cleaning apparatus;

FIG. 2A illustrates an overall view of an example of a semiconductor wafer cleaning apparatus according to this disclosure;

FIG. 2B illustrates an area enclosed by the three-point long chain line shown in FIG. 2A;

FIG. 3 illustrates the positioning of the spray ports of the two return portion rinse nozzles;

FIG. 4A illustrates a top view of the nozzle head in the cleaning apparatus related to Example 1 used in the example;

FIG. 4B illustrates the same related to Example 2;

FIG. 5A illustrates the cleaning effect on the recess of the nozzle head in Example 1; and

FIG. 5B illustrates the same in Example 2.

### DETAILED DESCRIPTION

### (Semiconductor Wafer Cleaning Apparatus)

The following is a description of the embodiment of this disclosure with reference to the drawings. The semiconductor wafer cleaning apparatus according to this disclosure comprises: a disk-shaped rotary table having a circular opening in the center and positioned horizontally; a wafer holder provided on the top surface of the rotary table to hold a semiconductor wafer to be cleaned; a cylindrical return portion provided on the bottom surface of the rotary table; a nozzle head having a centrally located inverted conical recess, and a horizontal portion disposed horizontally on the radially outer side of the recess, opposite to the bottom surface of the rotary table; a lower chemical supply nozzle provided in the recess of the nozzle head to supply chemical solution toward the back surface of the semiconductor wafer through the opening; and a wafer back surface rinse nozzle provided in the recess of the nozzle head to supply pure water toward the back surface of the semiconductor wafer through the opening. Here, the return portion is disposed near the opening, and a return portion rinse nozzle is provided in the recess of the nozzle head to supply pure water toward the return portion to rinse the return portion.

In order to suppress the generation of particles on the back surface of the semiconductor wafer W, the inventors have diligently studied the causes of particle generation. As a result, the inventors thought that the chemical solution scattered during the cleaning process adhered not only to the recess 14a of the nozzle head 14 but also to the return portion 13 on the bottom surface 11c of the rotary table 11, and that during the subsequent drying process, the chemical solution on the return portion 13 was carried by the airflow generated by the high-speed rotation of the rotary table 11 and adhered to the back surface of the semiconductor wafer W.

Therefore, the inventors considered supplying pure water from the wafer back surface rinse nozzle 16 to the return portion 13 to rinse the return portion 13. However, it is difficult to clean the return portion 13 while rinsing the back surface of the semiconductor wafer W using only the wafer back surface rinse nozzle 16. The inventors conceived of the idea of installing a return portion rinse nozzle separately in the recess 14a of the nozzle head 14 to supply pure water toward the return portion 13 to rinse the return portion 13, thereby completing this disclosure.

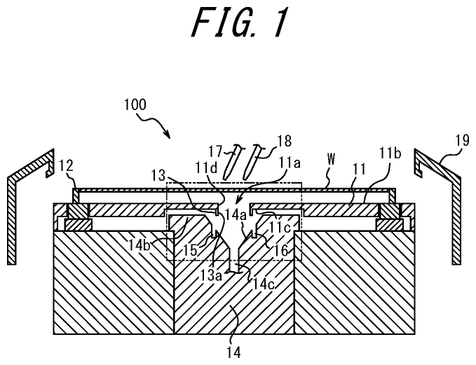

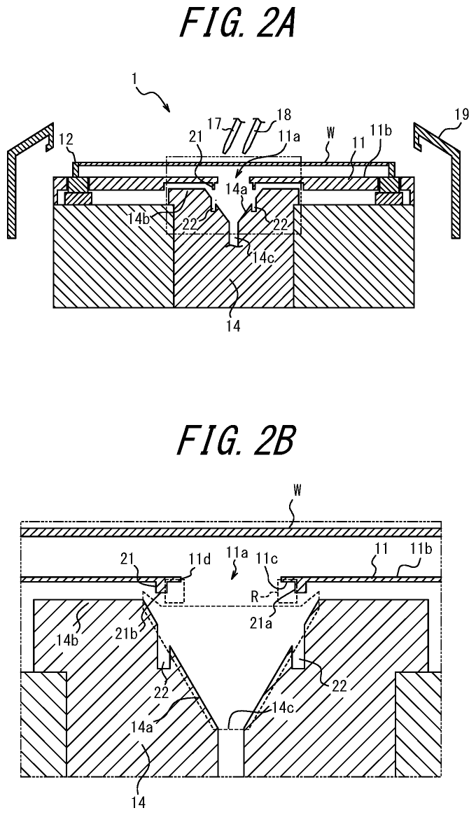

FIG. 2A illustrates an overall view of an example of a semiconductor wafer cleaning apparatus according to this disclosure, and FIG. 2B illustrates an area enclosed by the three-point long chain line shown in FIG. 2A. Note, the same configuration as shown in FIG. 1 is labeled with the same reference signs. The nozzle head 14 is provided with a lower chemical supply nozzle 15 and a wafer back surface rinse nozzle 16 in the recess 14a of the nozzle head 14 at locations around the circumference of the recess 14a not shown in the figure.

In the semiconductor wafer cleaning apparatus 1 illustrated in FIGS. 2A and 2B, the return portion 21 is disposed near the opening 11a of the rotary table 11. Specifically, the return portion 21 can be provided, as illustrated in FIG. 1, along the inner wall lid of the rotary table 11 defining the opening 11a of the rotary table 11. Alternatively, as illustrated in FIG. 2B, the return portion 21 can be disposed at a position radially outward from the inner wall lid of the rotary table 11 (i.e., the inner wall 21a of the return portion 21 is located radially outward from the inner wall lid of the rotary table 11). Of these two arrangements of the return portion 21, the return portion 21 is preferably disposed at a position radially outward from the inner wall lid of the rotary table 11. This arrangement creates a liquid reservoir area R between the bottom surface 11c of the rotary table 11 and the inner wall 21a of the return portion 21, where the pure water supplied from the return portion rinse nozzle 22 is reserved, and the pure water held in the liquid reservoir area R can be dropped to clean the nozzle head 14.

When the return portion 21 is disposed at a position radially outward from the inner wall 11d of the rotary table 11, the return portion 21 is preferably disposed at a position of 1 mm or more and 20 mm or less radially outward from the inner wall lid of the rotary table 11. By disposing the return portion 21 at a position of 1 mm or more radially outward from the inner wall lid of the opening 11a, the liquid reservoir area R which can retain a sufficient amount of pure water can be formed between the bottom surface 11c of the rotary table 11 and the inner wall 21a of the return portion 21, and this allows the held pure water to fall down to effectively clean the nozzle head 14. By disposing the return portion 21 at a position of 20 mm or less radially outward from the inner wall lid of the aperture 11a, it is possible to suppress uneven cleaning of the nozzle head 14 due to excessive spreading of the pure water in the liquid reservoir area R. In addition, this arrangement enables to suppress the larger size of the nozzle head 14 and thus of the cleaning system 1 due to the installation of the return portion rinse nozzle 22 on radially outward.

The return portion rinse nozzle 22 supplies pure water to the return portion 21 to rinse the return portion 21. The spray of pure water from the return portion rinse nozzle 22 is preferably directed so that it lands on the bottom end 21b of the return portion 21. For this purpose, the return portion rinse nozzle 22 is preferably disposed to spray pure water toward the return portion 21 at an angle of 0 or more to 30 or less degrees to the vertical direction. This allows pure water to be dispersed in both the radially outer area and the radially inner area of the return portion 21, and effectively cleaning the entire return portion 21.

Although only one return portion rinse nozzle 22 may be provided, it is preferable to provide a plurality of return portion rinse nozzles 22 as shown in FIG. 2. This allows the return portion 21 and the recess 14a of the nozzle head 14 to be cleaned efficiently and effectively.

When the plurality of return portion rinse nozzles 22 is provided, the plurality of return portion rinse nozzles 22 is preferably disposed at least 90 degrees apart from each other in the circumferential direction of the recess 14a of the nozzle head 14. This prevents the pure water supplied by one return portion rinse nozzle 22 from interfering with the pure water supplied by another return portion rinse nozzle 22. It is more preferable that the plurality of return portion rinse nozzles 22 is disposed as far apart from each other as possible.

When the plurality of return portion rinse nozzles 22 is provided, it is preferable to differentiate the radial positions of the return portion rinse nozzles 22. For example, when two of return portion rinse nozzles 22 are provided, the cleaning apparatus 1 preferably includes a first return portion rinse nozzle 22a, and a second return portion rinse nozzle 22b disposed radially inward from the first return portion rinse nozzle. This prevents the pure water supplied by the first return portion rinse nozzle 22a and retained in the liquid reservoir area R from being disturbed by the pure water supplied by the second return portion rinse nozzle 22b. As a result, the pure water held in the liquid reservoir area R falls more evenly on the recess 14a of the nozzle head 14, allowing the recess 14a of the nozzle head 14 to be cleaned more evenly.

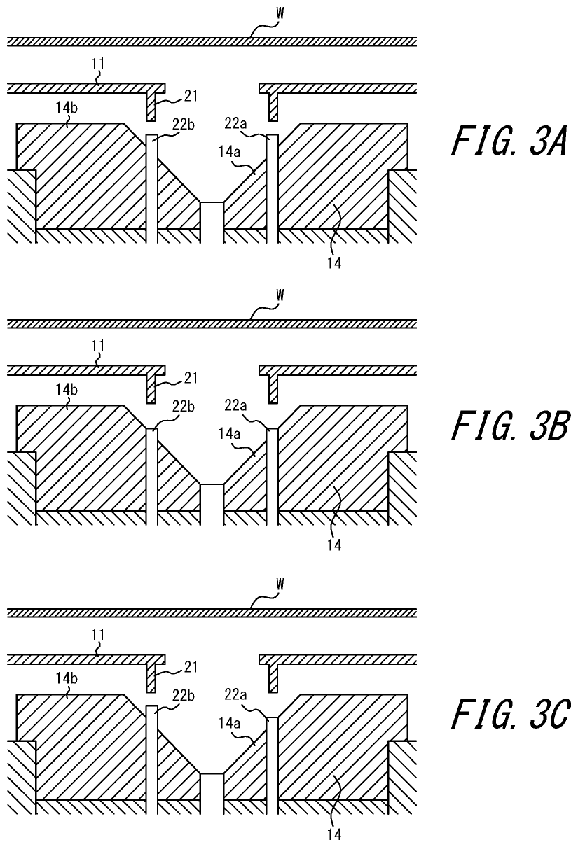

When two of return portion rinse nozzles 22 (the first return portion rinse nozzle 22a and the second return portion rinse nozzle 22b) are provided, as shown in FIG. 3, there are three possible positions of the spray ports of these nozzles: a pattern in which both spray ports protrude from the surface of the recess 14a (FIG. 3A); a pattern in which both spray ports do not protrude from the surface of the recess 14a (FIG. 3B); and a pattern in which one spray port protrudes from the surface of the recess 14a and the other spray port does not protrude from the surface of the recess 14a (FIG. 3C). Of these three patterns, the spray port of the second return portion rinse nozzle 22b, which is located radially inward, preferably protrude from the surface of the recess 14a of the nozzle head 14. This prevents interference between the pure water sprayed from the second return portion rinse nozzle 22b and the pure water falling from the liquid reservoir area R, allowing the recess 14a to be cleaned more evenly. Note, “The spray port of the nozzle does not protrude from the surface of the recess 14a” means that the height position of the nozzle top on the slope side of the recess 14a of the nozzle head 14 (radially outer side of the nozzle head 14) is the same as or lower than the height position of the slope of the recess 14 of the nozzle head 14. Therefore, the position of the nozzle top on radially inner side may be higher than the height position of the slope of the recess 14 of the nozzle head 14 (see nozzle 22a in FIGS. 3B and 3C).

The cleaning apparatus 1 preferably further comprises a gas supply nozzle (not shown) provided in the recess 14a of the nozzle head 14 to supply gas toward the back surface of the semiconductor wafer W thorough the opening 11a. In this case, the gas supply nozzle is preferably disposed at least 90 degrees away from the return portion rinse nozzle 22 in the direction of rotation of the rotary table 11. This prevents the pure water supplied from the return portion rinse nozzle 22 and retained in the liquid reservoir area R from being interfered with by the gas supplied from the gas supply nozzle.

### (Method for Cleaning a Semiconductor Wafer)

The method for cleaning a semiconductor wafer according to this disclosure is a method for cleaning semiconductor wafer to be cleaned using the semiconductor wafer cleaning apparatus described above. This method includes supplying pure water from the wafer back surface rinse nozzle toward the back surface of the semiconductor wafer to rinse the back surface of the semiconductor wafer, and simultaneously supplying pure water from the return portion rinse nozzle toward the return portion to rinse the return portion.

As described above, the semiconductor wafer cleaning apparatus 1 is provided with the return portion rinse nozzle 22 for cleaning the return portion 21 disposed near the opening 11a in the lower surface 11c of the rotary table 11. The method according to this disclosure supplies pure water from the wafer back surface rinse nozzle 16 toward the back surface of the semiconductor wafer W to rinse the back surface of the semiconductor wafer W, and simultaneously supplies pure water from the return portion rinse nozzle 22 toward the return portion 21 to rinse the return portion 21.

That is, during the rinsing process using pure water after the cleaning process of the semiconductor wafer using chemical solution, the return portion rinse nozzle 22 supplies pure water to the return portion 21. This allows the removal of chemical solution such as hydrogen fluoride that adhered to the return portion 21 during the cleaning process, thereby suppressing the generation of particles.

The semiconductor wafer W to be cleaned are not particularly limited, but a silicon wafer can be suitably cleaned.

In this disclosure, it is preferable to supply chemical solution from the lower chemical supply nozzle 15 toward the back surface of the semiconductor wafer W, and simultaneously supply pure water from the return portion rinse nozzle 22 toward the return portion 21 to rinse the return portion 21. That is, during the cleaning process using chemical solution, it is preferable to supply pure water from the return portion rinse nozzle 22 toward the return portion 21 to rinse the return portion 21. This prevents splashed chemical solution from adhering to the return portion 21 during the cleaning process, further reducing the generation of particles.

In addition, in this disclosure, it is preferable to use the cleaning apparatus 1 provided with the plurality of return portion rinse nozzles 22 to simultaneously supply pure water from the plurality of return portion rinse nozzles 22 to the return portion 21. This further enhances the cleaning effectiveness of the return portion 21 and the recess 14a of the nozzle head 14.

Further, it is preferable to use the cleaning apparatus 1 provided with two return portion rinse nozzles 22 (the first return portion rinse nozzle 22a and the second return portion rinse nozzle 22b), where the second return portion rinse nozzle 22b is disposed radially inward from the first return portion rinse nozzle 22a, to make the flow rate of pure water from the first return portion rinse nozzle 22a greater than the flow rate of pure water from the second return portion rinse nozzle 22b. This allows the pure water supplied by the first return portion rinse nozzle 22a and held in the liquid reservoir area R to be prevented from being disturbed by the pure water supplied by the second return portion rinse nozzle 22b, allowing the pure water held in the liquid reservoir area R to fall more evenly on the recess 14a of the nozzle head 14 to clean the recess 14a more evenly.

Furthermore, it is preferable to use the cleaning apparatus 1 provided with a gas supply nozzle to supply gas toward the back surface of the semiconductor wafer W, where the gas supply nozzle is disposed at least 90 degrees away from the return portion rinse nozzle 22 in the direction of rotation of the rotary table 11, to supply gas from the gas supply nozzle 23 toward the back surface of the semiconductor wafer W during at least rinsing the back surface of the semiconductor wafer W with pure water. This prevents the pure water supplied from the return portion rinse nozzle 22 and retained in the liquid reservoir area R from being interfered with by the gas supplied from the gas supply nozzle.

### (Method for Producing a Silicon Wafer)

The method for producing a silicon wafer according to this disclosure includes using the method for cleaning a semiconductor wafer according to this disclosure described above to clean a silicon wafer obtained by subjecting a silicon ingot grown by a prescribed method to a wafer processing process.

As described above, the semiconductor wafer cleaning method according to this disclosure supplies pure water from the wafer back surface rinse nozzle 16 toward the back surface of the semiconductor wafer W to rinse the back surface of the semiconductor wafer W, and simultaneously supplies pure water from the return portion rinse nozzle 22 toward the return portion 21 to rinse the return portion 21. Therefore, using the method according to this disclosure to clean a silicon wafer (pre-silicon wafer) obtained by subjecting a single-crystal silicon ingot grown by a prescribed method to a wafer processing process allows to obtain a silicon wafer with reduced particles.

The method for growing the single-crystal silicon ingot can be the CZ method or the floating zone (FZ) melting method.

### EXAMPLES

Examples of this disclosure are described below, but the disclosure is not limited to the examples.

### Example 1

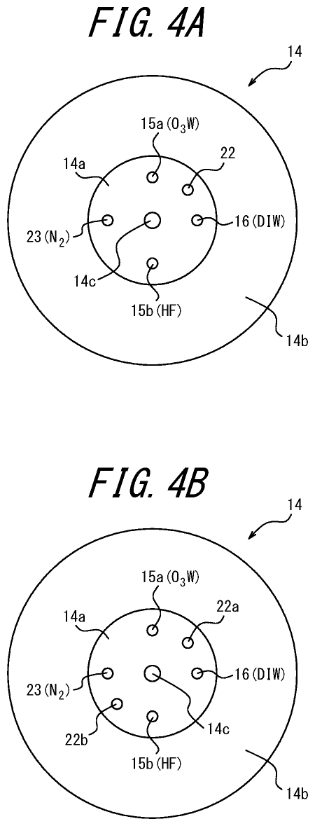

The front and back surfaces of silicon wafers were cleaned using the semiconductor wafer cleaning apparatus 1 according to this disclosure. Here, the cleaning apparatus 1 illustrated in FIG. 2 with only one return portion rinse nozzle 22 was used. The top view of the nozzle head in the cleaning apparatus 1 used for Example 1 is illustrated in FIG. 4A. As illustrated in FIG. 4A, the first lower chemical supply nozzle 15a, which supplies ozone water (O₃W), is disposed at 45 degrees counterclockwise of the return portion rinse nozzle 22, and the gas supply nozzle 23, which supplies N₂ gas, is disposed at 90 degrees counterclockwise of this first lower chemical supply nozzle 15a. In addition, the second lower chemical supply nozzle 15b, which supplies HF, is disposed at 90 degrees counterclockwise from the gas supply nozzle 23, and the wafer back surface rinse nozzle 16, which supplies pure water (DIW), is disposed at 90 degrees counterclockwise from this second lower chemical supply nozzle 15b. The return portion rinse nozzle 22 is disposed at a position directly below the return portion 21. The height of the spray ports for the chemical/pure water of: the first lower chemical supply nozzle 15a, the second lower chemical supply nozzle 15b, and the wafer back surface rinse nozzle 16 above are all the same, and as illustrated in FIG. 3B, they are disposed at the same height as the slope of the recess 14a of the nozzle head 14 and do not protrude from the recess 14a.

The front and back surfaces of three silicon wafers were cleaned using the above cleaning apparatus 1. Prior to this cleaning, particles on the back surface of each silicon wafer were detected as light point defects (LPD) using a surface inspection system (SP1 produced by KLA-Tencor), and the number of LPD with a size of 0.2 μm or larger was examined beforehand.

Each silicon wafer was specifically cleaned as follows. First, in the cleaning process, the silicon wafer was rotated at 500 rpm, and the supply of O₃W from the first lower chemical supply nozzle 15a and the upper chemical supply nozzle 17 and the supply of HF from the second lower chemical supply nozzle 15b and the upper chemical supply nozzle 17 were alternately and repeatedly carried out. Next, in the rinsing process, the supply of HF from the second lower chemical supply nozzle 15b and the upper chemical supply nozzle 17 was stopped while the rotation speed of silicon wafer was maintained at 500 rpm, and then DIW was supplied from the wafer back surface rinse nozzle 16 and the wafer front surface rinse nozzle 18 toward the front and back surfaces of the silicon wafer, and DIW was supplied from the return portion rinse nozzle 22 toward the return portion 21 to rinse the return portion 21. After that, in the drying process, the supply of DIW from the wafer back surface rinse nozzle 16 and the wafer front surface rinse nozzle 18 and the supply of DIW from the return portion rinse nozzle 22 were stopped, the silicon wafer was rotated at high speed at 1500 rpm, and N₂ gas was supplied from the gas supply nozzle 23 to dry the silicon wafer.

For each silicon wafer after cleaning, the particles on the back surface of the silicon wafer were detected as LPD in the same manner as before cleaning, and the number of LPD with a size of 0.2 μm or larger was examined to determine the increase in particles after cleaning.

### Example 2

The front and back surfaces of the silicon wafers were cleaned as in Example 1. However, as the cleaning apparatus 1, two return portion rinse nozzles 22 are provided in the recess 14a of the nozzle head 14, as illustrated in FIG. 4B. The first return portion rinse nozzle 22a is disposed at a position directly below the return portion 21, and the second return portion rinse nozzle 22b is disposed at a position 0.7 mm radially inward from the first return portion rinse nozzle 22a and 1 mm higher than the first return portion rinse nozzle 22a. All other conditions are the same as in Example 1. As in Example 1, the number of particles on the back surface of the silicon wafer after cleaning was examined, and the amount of increase in particles after cleaning was determined.

### Comparative Example

The front and back surfaces of the silicon wafer was cleaned as in Example 1. However, as a cleaning device, the one without a return portion rinse nozzle as illustrated in FIG. 1 was used. All other conditions are the same as in Example 1. As in Example 1, the number of particles on the back surface of the silicon wafer after cleaning was examined, and the amount of increase in particles after cleaning was determined.

<Amount of Increase in Particles after Cleaning>

First, for the silicon wafer in Comparative Example, the number of particles (LPD) increased by 10 to 40 after cleaning. In contrast, for the silicon wafer in Example 1, the number of LPDs increased by only two to three after cleaning. And for silicon wafer in Example 2, the number of LPDs did not change after cleaning. This shows that the present disclosure can suppress the generation of particles on the back surface of the silicon wafer.

### <Effectiveness of Cleaning on Recess of Nozzle Head>

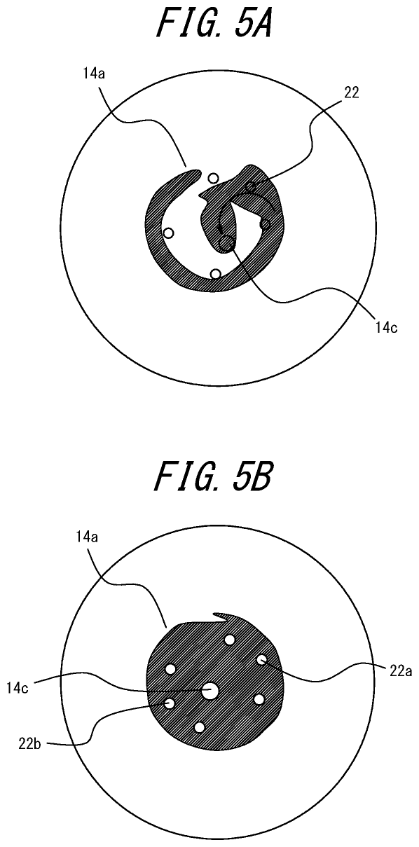

FIG. 5A illustrates the cleaning effect on the recess 14a of the nozzle head 14 in Example 1 and FIG. 5B illustrates the same in Example 2. As illustrated in FIG. 5A, for Example 1 in which one return portion rinse nozzle 22 is provided, the pure water does not flow evenly over the recess 14a. In contrast, as illustrated in FIG. 5B, for Example 2 in which two return portion rinse nozzles 22 are provided, the pure water flows more evenly over the recess 14a than in Example 1. Therefore, it is believed that Example 2 can clean the recess 14a of the nozzle head 14 better than Example 1.

### INDUSTRIAL APPLICABILITY

This disclosure is useful in the semiconductor wafer manufacturing industry because it can suppress the generation of particles on the back surface of the semiconductor wafer.

### REFERENCE SIGNS LIST

1,100 Semiconductor wafer cleaning apparatus
11 Rotary table
11a Opening
11b Top surface
11c Bottom surface
11d Inner wall
12 Wafer holder
13,21 Return portion
14 Nozzle head
14a Recess
14b Horizontal portion
14c Liquid drainage port
15 Lower chemical supply nozzle
15a First lower chemical supply nozzle
15b Second lower chemical supply nozzle
16 Wafer back surface rinse nozzle
17 Upper chemical supply nozzle
18 Wafer front surface rinse nozzle
19 Spin cup
22 Return portion rinse nozzle
22a First return portion rinse nozzle
22b Second return portion rinse nozzle
23 Gas supply nozzle
W Semiconductor wafer

1. A semiconductor wafer cleaning apparatus comprising:
a disk-shaped rotary table having a circular opening in the center and positioned horizontally;
a wafer holder provided on the top surface of the rotary table to hold a semiconductor wafer to be cleaned;
a cylindrical return portion provided on the bottom surface of the rotary table;
a nozzle head having a centrally located inverted conical recess, and a horizontal portion disposed horizontally on the radially outer side of the recess, opposite to the bottom surface of the rotary table;
a lower chemical supply nozzle provided in the recess of the nozzle head to supply chemical solution toward the back surface of the semiconductor wafer through the opening; and
a wafer back surface rinse nozzle provided in the recess of the nozzle head to supply pure water toward the back surface of the semiconductor wafer through the opening; wherein,
the return portion is disposed near the opening, and
a return portion rinse nozzle is provided in the recess of the nozzle head to supply pure water toward the return portion to rinse the return portion.

2. The semiconductor wafer cleaning apparatus according to claim 1, wherein the return portion is disposed at a position radially outward from an inner wall of the rotary table defining the opening.

3. The semiconductor wafer cleaning apparatus according to claim 2, wherein the return portion is disposed at a position of 1 mm or more to 20 mm or less radially outward from the inner wall of the rotary table defining the opening.

4. The semiconductor wafer cleaning apparatus according to claim 1, wherein a plurality of the return portion rinse nozzles is provided.

5. The semiconductor wafer cleaning apparatus according to claim 4, wherein the plurality of return portion rinse nozzles is disposed at least 90 degrees apart from each other in the circumferential direction of the recess.

6. The semiconductor wafer cleaning apparatus according to claim 4, wherein the plurality of return portion rinse nozzles includes a first return portion rinse nozzle, and a second return portion rinse nozzle disposed radially inward from the first return portion rinse nozzle.

7. The semiconductor wafer cleaning apparatus according to claim 6, wherein a spray port for spraying pure water in the second return portion rinse nozzle protrudes from the surface of the recess.

8. The semiconductor wafer cleaning apparatus according to claim 1, further comprising a gas supply nozzle provided in the recess of the nozzle head to supply gas toward the back surface of the semiconductor wafer thorough the opening, the gas supply nozzle is disposed at least 90 degrees away from the return portion rinse nozzle in the direction of rotation of the rotary table.

9. The semiconductor wafer cleaning apparatus according to claim 1, wherein the return portion rinse nozzle is disposed to spray pure water toward the return portion at an angle of 0 or more to 30 or less degrees to the vertical direction.

10. A method for cleaning a semiconductor wafer to be cleaned using the semiconductor wafer cleaning apparatus according to claim 1, wherein the method includes:
supplying pure water from the wafer back surface rinse nozzle toward the back surface of the semiconductor wafer to rinse the back surface of the semiconductor wafer, and simultaneously supplying pure water from the return portion rinse nozzle toward the return portion to rinse the return portion.

11. The method for cleaning a semiconductor wafer according to claim 10, wherein the method includes supplying chemical solution from the lower chemical supply nozzle toward the back surface of the semiconductor wafer, and simultaneously supplying pure water from the return portion rinse nozzle toward the return portion to rinse the return portion.

12. The method for cleaning a semiconductor wafer according to claim 10, wherein the method includes using the semiconductor wafer cleaning apparatus according to any one of claims 4 to 7 to simultaneously supply pure water from the plurality of return portion rinse nozzles toward the return portion.

13. The method for cleaning a semiconductor wafer according to claim 12, wherein the method includes using the semiconductor wafer cleaning apparatus according to claim 6 or 7 to make the flow rate of pure water from the first return portion rinse nozzle greater than the flow rate of pure water from the second return portion rinse nozzle.

14. The method for cleaning a semiconductor wafer according to claim 10, wherein the method includes using the semiconductor wafer cleaning apparatus according to claim 8 to supply gas from the gas supply nozzle toward the back surface of the semiconductor wafer during at least rinsing the back surface of the semiconductor wafer with pure water.

15. The method for cleaning a semiconductor wafer according to claim 10, wherein the semiconductor wafer is a silicon wafer.

16. A method for producing a silicon wafer, wherein the method includes using the method for cleaning a semiconductor wafer according to claim 15 to clean a silicon wafer obtained by subjecting a single-crystal silicon ingot grown by a prescribed method to a wafer processing process.
